(19) United States
(12) Patent Application Publication
(10) Pub. No.: US 2025/0105026 A1
(43) Pub. Date: Mar. 27, 2025

(54) APPARATUS AND METHOD FOR PROCESSING SUBSTRATE

(71) Applicant: SEMES CO., LTD., Cheonan-si (KR)

(72) Inventors: Kyung Taek IM, Cheonan-si (KR); Jae Ha KIM, Suwon-si (KR); Gui Hun KIM, Cheonan-si (KR)

(21) Appl. No.: 18/810,501

(22) Filed: Aug. 20, 2024

(30) Foreign Application Priority Data
Sep. 26, 2023 (KR) 10-2023-0129053

(51) Int. Cl. H01L 21/67; G03F 7/16

(52) U.S. Cl. CPC H01L 21/67017; G03F 7/168

(57) ABSTRACT

An apparatus for processing a substrate includes a heating unit heating the substrate and including a hot plate having a vacuum hole; a fume collection unit including a housing, an inlet portion connected to the vacuum hole and introducing a mixed gas containing fumes generated in heating the substrate within an internal space of the housing, and an outlet portion discharging a gas from which the fumes have been removed to an external space of the housing; a vacuum unit connected to the fume collection unit and vacuum-adsorbing the substrate onto the hot plate when the substrate is heated; and a chilling unit including a cooling body, a coolant inflow fluid passage introducing a coolant into the cooling body, a coolant discharge fluid passage discharging the coolant from the cooling body, and a bypass fluid passage connecting the coolant inflow fluid passage and the coolant discharge fluid passage.

### CROSS-REFERENCE TO RELATED APPLICATION(S)

This application claims benefit of priority to Korean Patent Application No. 10-2023-0129053 filed on Sep. 26, 2023 in the Korean Intellectual Property Office, the disclosure of which is incorporated herein by reference in its entirety.

### BACKGROUND

### 1. Field

The present disclosure relates to an apparatus for processing a substrate and a method for processing the substrate.

### 2. Description of Related Art

In order to manufacture semiconductor devices, a predetermined pattern should be formed on a substrate such as a wafer. When forming such a predetermined pattern on the substrate, a deposition process, a lithography process, an etching process, and the like may be continuously performed.

When performing the lithography process among the above processes, the substrate may be heat-treated in a bake chamber. When the substrate is heat-treated in the bake chamber, a lift pin may position the substrate on a hot plate and may then heat-treat the substrate. At this time, a vacuum hole may be formed in the hot plate to fix the substrate.

When fumes generated in heating the substrate are discharged along airflow toward the vacuum hole, the bake chamber or auxiliary equipment connected to the bake chamber (e.g., coolant supply device, vacuum pump, etc.) may cause contamination or cause problems. To solve this, a fume collection device for collecting and removing the fumes may be installed in a substrate processing device. As the fume collection device is constantly cooled by a cooling device, there may be a problem in that the fumes are cooled and settle at an inlet portion into which the airflow is introduced from the bake chamber, and clog the inlet portion.

### SUMMARY

An aspect of the present disclosure is to solve the problems detailed above, and is intended to provide an apparatus for processing a substrate and a method for processing the substrate, that may prevent problems such as blockage of fluid passage, equipment contamination, or the like, caused by fumes generated during a heat-treatment process of the substrate and a mixed gas containing the fumes.

According to an aspect of the present disclosure, an apparatus for processing a substrate includes a heating unit heating the substrate and including a hot plate having a vacuum hole; a fume collection unit including a housing, an inlet portion connected to the vacuum hole and introducing a mixed gas containing fumes generated in heating the substrate within an internal space of the housing, and an outlet portion discharging a gas from which the fumes have been removed to an external space of the housing; a vacuum unit connected to the fume collection unit and vacuum-adsorbing the substrate onto the hot plate when the substrate is heated; and a chilling unit disposed adjacently to the fume collection unit, and including a cooling body, a coolant inflow fluid passage introducing a coolant into the cooling body, a coolant discharge fluid passage discharging the coolant from the cooling body, and a bypass fluid passage connecting the coolant inflow fluid passage and the coolant discharge fluid passage.

According to an aspect of the present disclosure, a method for processing a substrate includes supplying the substrate to a hot plate provided in a heating unit; vacuum-adsorbing the substrate onto the hot plate by a vacuum unit; collecting fumes from a mixed gas introduced from the heating unit by a fume collection unit; and selectively cooling the fume collection unit or stopping the cooling by a chilling unit.

According to an aspect of the present disclosure, an apparatus for processing a substrate includes an application module applying a processing liquid to the substrate; a heating unit disposed on one side of the application module, receiving and heating the substrate on which the application of the processing liquid has been completed, and including a hot plate having a vacuum hole; a fume collection unit including a housing, an inlet portion connected to the vacuum hole and introducing a mixed gas containing fumes generated in heating the substrate within an internal space of the housing, and an outlet portion discharging a gas from which the fumes have been removed to an external space of the housing; a chilling unit disposed on one side of the fume collection unit, and including a coolant supply unit, a cooling body spaced apart from the coolant supply unit, a coolant inflow fluid passage introducing a coolant supplied from the coolant supply unit into the cooling body, a coolant discharge fluid passage discharging the coolant from the cooling body, and a bypass fluid passage disposed between the coolant supply unit and the cooling body and connecting the coolant inflow fluid passage and the coolant discharge fluid passage; a vacuum unit connected to the fume collection unit, vacuum-adsorbing the substrate onto the hot plate when the substrate is heated, and converting between an active state in which the substrate is vacuum-adsorbed on the hot plate and a non-active state in which the vacuum-adsorption of the substrate stops; and a controller controlling the chilling unit to selectively cool the fume collection unit, based on whether the vacuum unit is in the active state or whether the substrate is supplied to the heating unit, wherein the controller controls the coolant to be supplied to the chilling unit, when the substrate is seated on the hot plate and the vacuum unit is converted to the active state, and controls the coolant to move to the coolant discharge fluid passage through the bypass fluid passage, immediately before or immediately after the substrate is discharged from the hot plate.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a view of an apparatus for processing a substrate according to an embodiment of the present disclosure, viewed from above.

FIG. 2 is a view of the apparatus of FIG. 1, viewed in an A-A direction.

FIG. 3 is a view of the apparatus of FIG. 1, viewed in a B-B direction.

FIG. 4 schematically illustrates a fume processing module provided in a conventional apparatus for processing a substrate.

FIG. 5 schematically illustrates a state in which a coolant moves through a bypass fluid passage in a fume processing module according to an embodiment of the present disclosure.

FIG. 6 schematically illustrates a state in which a coolant is supplied to a chilling unit in the fume processing module of FIG. 5.

FIG. 7 is a perspective view illustrating a fume collection unit and a chilling unit according to an embodiment of the present disclosure.

FIG. 8 schematically illustrates a state in which a coolant moves through a bypass fluid passage in a fume processing module according to another embodiment of the present disclosure.

FIG. 9 schematically illustrates a state in which a coolant begins to be supplied to a chilling unit in the fume processing module of FIG. 8.

FIG. 10 schematically illustrates a state in which a coolant is supplied to a chilling unit in the fume processing module of FIG. 8.

FIG. 11 is a flowchart illustrating a method for processing a substrate using a fume processing module according to the present disclosure.

FIG. 12 is a flowchart illustrating some steps of the method of FIG. 11.

### DETAILED DESCRIPTION

Hereinafter, with reference to the attached drawings, preferred embodiments will be described in detail such that those skilled in the art may easily practice the present disclosure. However, when describing preferred embodiments of the present disclosure in detail, and when it is determined that a detailed description of a related known function or configuration may unnecessarily obscure the gist of the present disclosure, the detailed description will be omitted. In addition, the same symbols may be used throughout the drawings for parts that perform similar functions and actions. In addition, in this specification, terms such as ‘on,’ ‘upper portion,’ ‘upper end,’ ‘below,’ ‘lower portion,’ ‘lower end,’ and the like may be based on the drawings, and terms such as ‘in,’ ‘within,’ ‘inside,’ ‘outside,’ and the like may also be based on an outer edge of a component corresponding thereto, and may actually vary depending on a direction in which an element or a component is disposed.

In addition, throughout the specification, ‘including’ a certain component means that other elements may be further included, rather than excluding another component, unless specifically stated to the contrary.

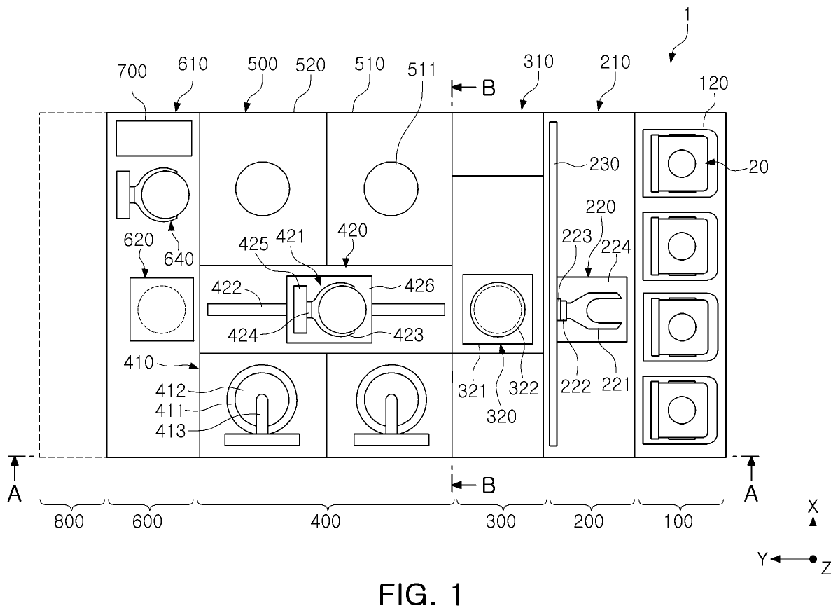

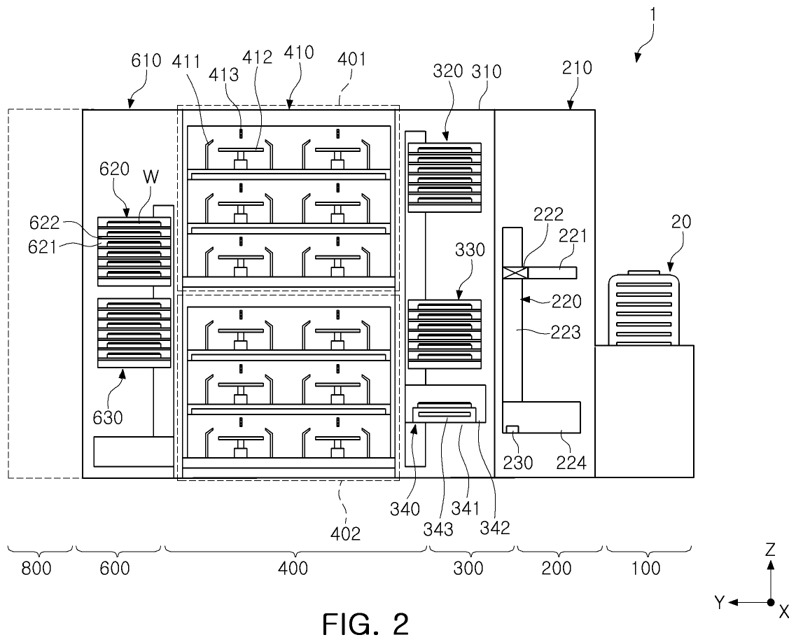

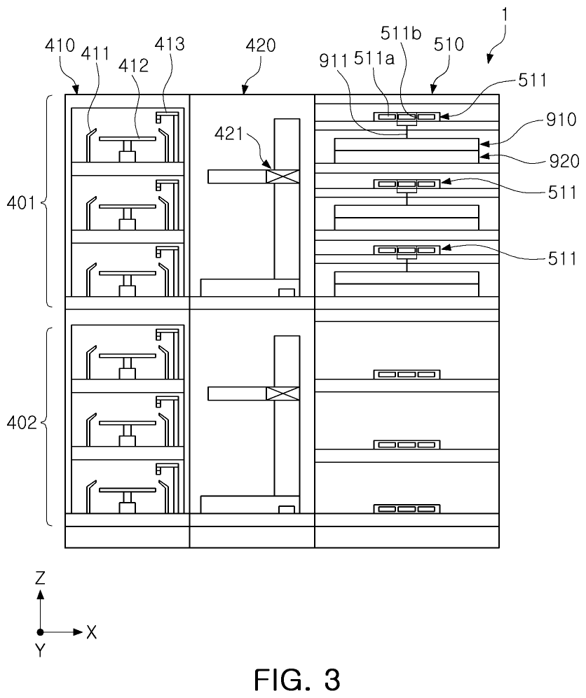

FIG. 1 is a view of an apparatus for processing a substrate, viewed from above, FIG. 2 is a view of the apparatus of FIG. 1, viewed in an A-A direction, and FIG. 3 is a view of the apparatus of FIG. 1, viewed in a B-B direction.

Referring to FIGS. 1 to 3, an apparatus 1 for processing a substrate may include a load port 100, an index module 200, a buffer module 300, an applying/development module 400, an interface module 600, and a purge module 700. The load port 100, the index module 200, the buffer module 300, the applying/development module 400, and the interface module 600 may be sequentially arranged in one direction. The purge module 700 may be provided in the interface module 600. The purge module 700 may be provided in various positions, such as in a position in which an exposure device 800 is connected to a rear end of the interface module 600, a side portion of the interface module 600, or the like. Hereinafter, a direction in which the load port 100, the index module 200, the buffer module 300, the applying/development module 400, and the interface module 600 are arranged may be referred to as a first direction Y, a direction, perpendicular to the first direction Y, when viewed from above, may be referred to as a second direction X, and a direction, perpendicular to the first direction Y and the second direction X, may be referred to as a third direction Z.

Additionally, the apparatus 1 may further include a fume processing module 900. The fume processing module 900 may include a fume collection unit 910, a chilling unit 920, and a vacuum unit 930, which will be described in detail later.

A substrate W may move in a state of being accommodated in a cassette 20. The cassette 20 may have a structure that may be sealed from the external environment. For example, a front opening unified pod (FOUP) having a door in a front direction may be used as the cassette 20.

Hereinafter, the load port 100, the index module 200, the buffer module 300, the applying/development module 400, the interface module 600, and the purge module 700 will be described in detail.

The load port 100 may have a placing table 120 on which the cassette 20 in which the substrate W is accommodated is disposed. The placing table 120 may be provided in plural, and the plurality of placing tables 120 may be arranged in a row in the second direction X. FIG. 1 illustrates an example in which four placing tables 120 are provided, but the number thereof may be changed.

The index module 200 may transfer the substrate W between the cassette 20 disposed on the placing table 120 of the load port 100, and the buffer module 300. The index module 200 may include a frame 210, an index robot 220, and a guide rail 230.

The frame 210 may be generally provided in a rectangular hexahedral shape having an empty interior, and may be disposed between the load port 100 and the buffer module 300. The frame 210 of the index module 200 may be provided on a lower height than a frame 310 of the buffer module 300.

The index robot 220 and the guide rail 230 may be arranged in the frame 210. The index robot 220 may be provided such that a gripper 221, which directly handles the substrate W, may move and rotate in the first direction Y, the second direction X, and the third direction Z. The index robot 220 may include the gripper 221, an arm 222, a support 223, and a pedestal 224. The gripper 221 may be fixedly installed on the arm 222. The arm 222 may be provided to as a stretchable structure or a rotatable structure. A longitudinal direction of the support 223 may be disposed in the third direction Z. The arm 222 may be coupled to the support 223 to be movable along the support 223. The support 223 may be fixedly coupled to the pedestal 224. The guide rail 230 may be provided such that a longitudinal direction thereof is disposed in the second direction X. The pedestal 224 may be coupled to the guide rail 230 to move linearly along the guide rail 230. In addition, although not illustrated, the frame 210 may be further provided with a door opener for opening and closing the door of the cassette 20.

The buffer module 300 may include the frame 310, a first buffer 320, a second buffer 330, and a cooling chamber 340. The frame 310 may be provided in a rectangular hexahedral shape having an empty interior, and may be disposed between the index module 200 and the applying/development module 400. The first buffer 320, the second buffer 330, and the cooling chamber 340 may be located in the frame 310. The cooling chamber 340, the second buffer 330, and the first buffer 320 may be sequentially arranged in the third direction Z from below. The first buffer 320 may be located on a height corresponding to an application module 401 of the applying/development module 400, and the second buffer 330 and the cooling chamber 340 may be located on a height corresponding to a development module 402 of the applying/development module 400.

The first buffer 320 and the second buffer 330 may temporarily store a plurality of substrates W, respectively. The first buffer 320 may have a housing 321 and a plurality of supports 322. In the first buffer 320, the supports 322 may be disposed in the housing 321, and may be spaced apart from each other in the third direction Z. The second buffer 330 may have a housing 331 and a plurality of supports 332. In the second buffer 330, the supports 332 may be disposed in the housing 331, and may be spaced apart from each other in the third direction Z. One substrate W may be disposed on each of the supports 322 of the first buffer 320 and each of the supports 332 of the second buffer 330. The housing 331 may have an opening in a direction in which the index robot 220 is provided such that the index robot 220 may load or unload the substrate W into or out of the support 332 in the housing 331.

The first buffer 320 may have a generally similar structure to the second buffer 330. The housing 321 of the first buffer 320 may have an opening in a direction in which a first buffer robot 360 is provided, and in a direction in which an application robot 421 located in an application module 401 is provided. The number of supports 322 provided in the first buffer 320 may be the same as or different from the number of supports 332 provided in the second buffer 330. According to an example, the number of supports 332 provided in the second buffer 330 may be greater than the number of supports 322 provided in the first buffer 320.

The cooling chambers 340 may cool the substrate W, respectively. The cooling chamber 340 may include a housing 341 and a chilling plate 342. The chilling plate 342 may have an upper surface on which the substrate W is disposed, and a cooling means 343 for cooling the substrate W. As the cooling means 343, various methods may be used, such as cooling using a coolant, cooling using a thermoelectric element, or the like. Additionally, the cooling chamber 340 may be provided with a lift pin assembly for locating the substrate W on the chilling plate 342. The housing 341 may have an opening in a direction in which the index robot 220 is provided and in a direction in which a developing robot provided in the developing module 402 is provided, such that the index robot 220 and the developing robot provided in the developing module 402 load or unload the substrate W to the chilling plate 342. Additionally, the cooling chamber 340 may be provided with doors opening and closing the above-described openings.

In the above, the buffer module 300 has been described as an embodiment including a configuration of the cooling chamber 340, but the present disclosure is not limited thereto, and the configuration of the cooling chamber 340 may be omitted, as necessary.

The application module 401 may include a process of applying a photosensitive liquid such as a photoresist to the substrate W, and a heat-treatment process such as heating and cooling of the substrate W before and after a resist application process. The application module 401 may have an application chamber 410, a heat-treatment chamber unit 500, and a transfer chamber 420. The application chamber 410, the transfer chamber 420, and the heat-treatment chamber unit 500 may be sequentially arranged in the second direction X. For example, based on the transfer chamber 420, the application chamber 410 may be provided on one side of the transfer chamber 420, and the heat-treatment chamber unit 500 may be provided on the other side of the transfer chamber 420.

The application chamber 410 may be provided in plural, and each of the plurality of application chambers 410 may be provided in plural in the third direction Z. Additionally, as illustrated in FIG. 1, the application chamber 410 may be provided in plural in the first direction Y, or may be provided in singular in the first direction Y.

The heat-treatment chamber unit 500 may include a baking chamber 510 and a cooling chamber 520, and the baking chamber 510 and the cooling chamber 520 may be provided in plural, respectively, in the third direction Z. The transfer chamber 420 may be located parallel to the first buffer 320 of the buffer module 300 in the first direction Y. The application robot 421 and a guide rail 422 may be located in the transfer chamber 420. The transfer chamber 420 may have a generally rectangular shape. The application robot 421 may transfer the substrate W between the baking chamber 510, the cooling chamber 520, the application chamber 410, and the first buffer 320 of the buffer module 300.

The guide rail 422 may be disposed such that a longitudinal direction thereof is parallel to the first direction Y. The guide rail 422 may guide the application robot 421 to move linearly in the first direction Y. The application robot 421 may have a gripper 423, an arm 424, a support 425, and a pedestal 426. The gripper 423 may be fixedly installed on the arm 424. The arm 424 may be provided as a stretchable structure such that the gripper 423 may move in a horizontal direction. The support 425 may be provided such that a longitudinal direction thereof is disposed in the third direction Z. The arm 424 may be coupled to the support 425 to move linearly in the third direction Z along the support 425. The support 425 may be fixedly coupled to the pedestal 426, and the pedestal 426 may be coupled to the guide rail 422 to be movable along the guide rail 422.

The application chambers 410 may all have the same structure, but types of processing liquids used in each of the application chambers 410 may be different. As a processing liquid, a processing liquid for forming a photoresist film or an anti-reflection film may be used.

The application chamber 410 may apply a processing liquid to the substrate W. The application chamber 410 may be provided with a processing unit including a processing vessel 411, a support portion 412, and a nozzle portion 413.

As an example, one processing unit may be disposed in each of the application chambers 410 in the first direction Y, but the present disclosure is not limited thereto, and two or more processing units may be disposed in one application chamber 410. Each of the processing units may have the same structure. Types of processing liquids used in each of the processing units may be different from each other. The processing vessel 411 of the application chamber 410 may have a shape exposed in an upward direction. The support portion 412 may be located in the processing vessel 411, and may support the substrate W. The support portion 412 may be provided to be rotatable. The nozzle portion 413 may supply a processing liquid onto the substrate W disposed on the support unit 412. The processing liquid may be applied to the substrate W using a spin coat method. In addition, a nozzle (not illustrated) for supplying a cleaning liquid such as deionized water (DIW) to clean a surface of the substrate W on which the processing liquid is applied, and a back rinse nozzle (not illustrated) for cleaning a lower surface of the substrate W may be optionally further provided in the application chamber 410.

In the baking chamber 510, when the substrate W is seated by the application robot 421, the substrate W may be heat-treated. In the baking chamber 510, a prebaking process for removing organic matter or moisture from the surface of the substrate W by heating the substrate W to a predetermined temperature, before applying the processing liquid, a soft baking process performed after applying the processing liquid to the wafer W, or the like may be performed, and a cooling process performed to cool the substrate W after each heating process, or the like may be performed.

The bake chamber 510 may be provided with a hot plate 511 and a heating means 511a. Hereinafter, the bake chamber 510, and the hot plate 511 and the heating means 511a, disposed therein, will be referred to as a heating unit HU. Additionally, the bake chamber 510 may be further equipped with a chilling plate (not illustrated). The chilling plate may cool the substrate W by receiving a coolant from a chilling unit 910, which will be described later. As a result, it is possible to prevent the substrate W from being heated to an excessively high temperature during a heat-treatment process. The substrate W on which the heat-treatment process has been completed may be transported to the cooling chamber 520.

The heating means 511a may heat the substrate W disposed in the bake chamber 510. In this case, the substrate W may be heated while the bake chamber 510 is sealed, and the heating means 511a may heat an entire region of the substrate W to a uniform temperature. This heat-treatment process may blow and remove organic substances on a liquid film formed by applying the processing liquid to the substrate W, to stabilize the liquid film. As the heating means 511a, various methods may be used, such as a heating method using a heating wire provided in an internal space or on an external surface of the hot plate 511, or a heating method using a heater disposed in an internal space or an external space of the bake chamber 510.

In the cooling chamber 520, a cooling process may be performed to cool the substrate W before applying the processing liquid. The cooling chamber 520 may be provided with a chilling plate. The chilling plate may include a cooling means that may be used in various manners to cool the substrate W, such as cooling using a coolant, cooling using a thermoelectric element, or the like.

The interface module 600 may connect the applying/development module 400 to the exposure device 800 externally. The interface module 600 may include an interface frame 610, a first interface buffer 620, a second interface buffer 630, and a transfer robot 640, and, after an operation of the applying/development module 400 is completed, the transfer robot 640 may transfer the substrate returned to the first and second interface buffers 620 and 630 to the exposure device 800. The first interface buffer 620 may include a housing 621 and a support 622, and the transfer robot 640 may load/unload the substrate W into/out of the support 622.

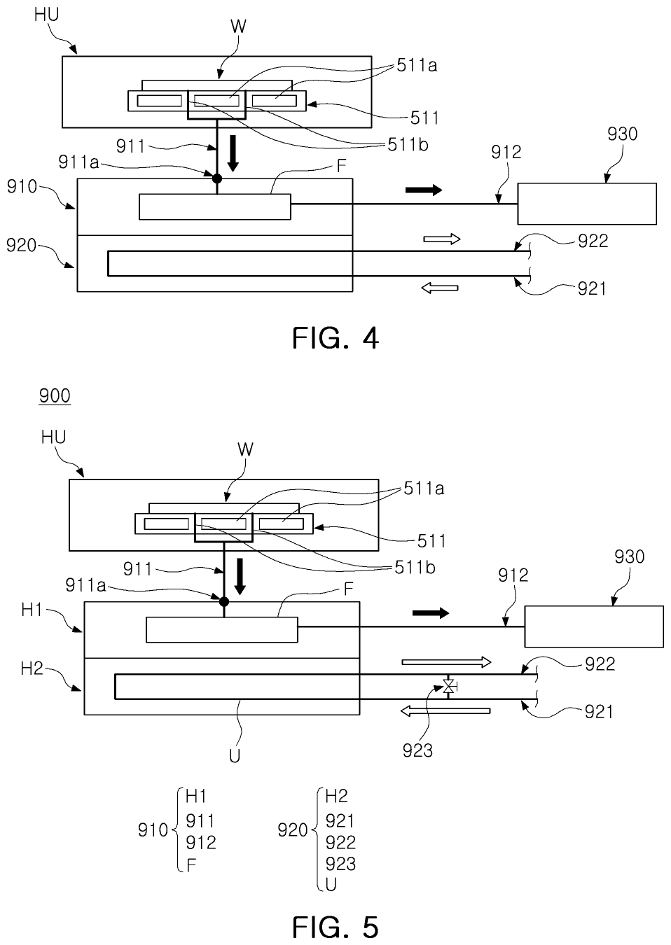

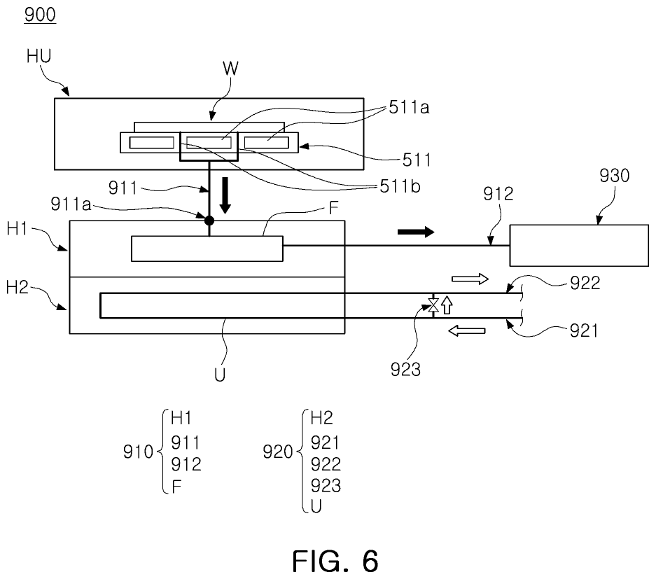

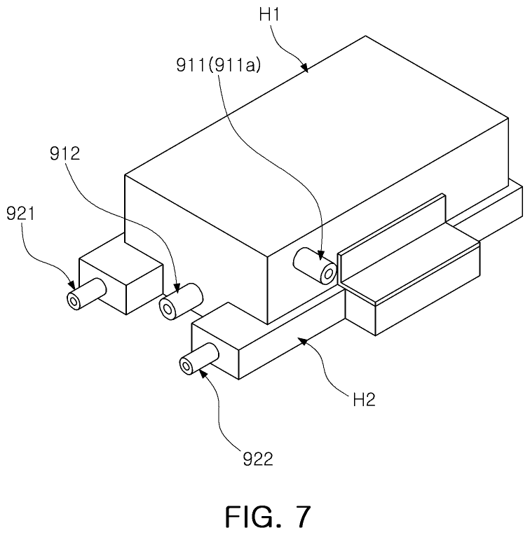

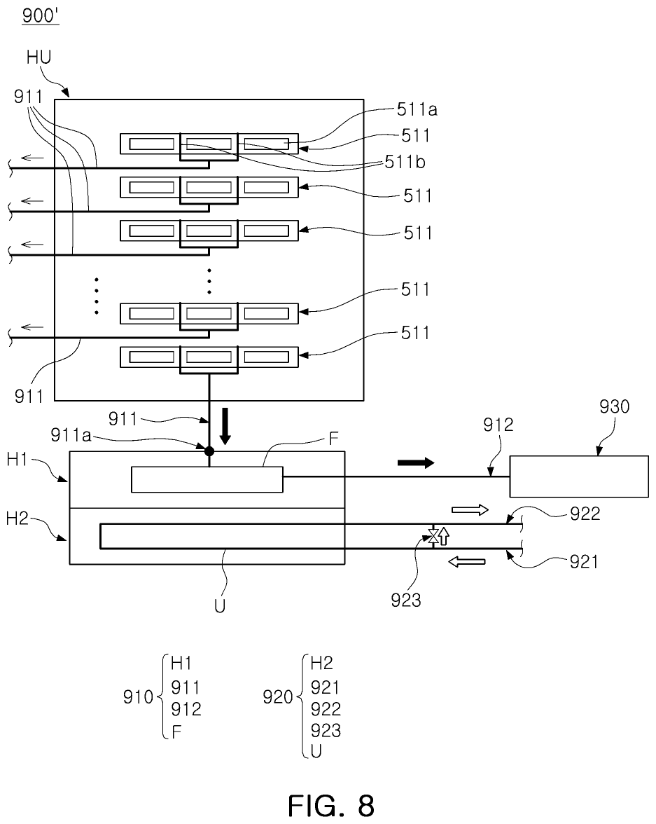

FIG. 4 schematically illustrates a fume processing module provided in a conventional apparatus for processing a substrate. FIG. 5 schematically illustrates a state in which a coolant moves through a bypass fluid passage in a fume processing module according to an embodiment of the present disclosure. FIG. 6 schematically illustrates a state in which a coolant is supplied to a chilling unit in the fume processing module of FIG. 5. FIG. 7 is a perspective view illustrating a fume collection unit and a chilling unit according to an embodiment of the present disclosure.

First, referring to FIGS. 5 and 6, a fume processing module 900 may include a fume collection unit 910, a chilling unit 920, and a vacuum unit 930. The fume collection unit 910 may be a device for collecting and removing fumes generated when a substrate W is heated. The fume collection unit 910 may prevent the fumes from flowing into other equipment (e.g., a coolant supply device, a vacuum pump, etc.) and causing the occurrence of contamination or damage. In this case, the fume collection unit 910 may include a housing H1, an inlet portion 911, and an outlet portion 912.

The inlet portion 911 may be a passage through which a mixed gas containing the fumes flows into the housing H1. The inlet portion 911 may be disposed between a heating unit HU and the fume collection unit 910. More specifically, one end of the inlet portion 911 may be connected to the heating unit HU, and the other end of the inlet portion 911 may be connected to an internal space of the fume collection unit 910. The one end of the inlet portion 911 may communicate with a vacuum hole 511b provided in a hot plate 511. In this case, a portion in which the other end of the inlet portion 911 and the fume collection unit 910 are connected will be referred to as a connection portion 911a.

The outlet portion 912 may be a passage through which gas from which the fumes have been removed is discharged to an external space of the fume collection unit 910. The outlet portion 912 may be connected to the vacuum unit 930. In this case, one end of the outlet portion 912 may be connected to the fume collection unit 910, and the other end of the outlet portion 912 may be connected to the vacuum unit 930. In this case, a fume trap portion F filtering the fumes from the mixed gas may be provided in the housing H1. When the mixed gas flows into an internal space of the housing H1 through the inlet portion 911, the fumes may be separated from the mixed gas while passing through the fume trap portion F. The mixed gas from which the fumes have been removed in this manner may be discharged to an external space of the housing H1 through the outlet portion 912.

The chilling unit 920 may cool the fume collection unit 910, which may be heated during a fume collection process. The chilling unit 920 may be disposed on one side of the fume collection unit 910, to be adjacently to the fume collection unit 910. In the drawings, the chilling unit 920 is illustrated as being disposed below the fume collection unit 910, but the present disclosure is not limited thereto.

The chilling unit 920 may include a cooling body H2, a coolant inflow fluid passage 921, and a coolant discharge fluid passage 922. Additionally, the chilling unit 920 may further include a coolant supply unit (not illustrated) for supplying a coolant. In this case, an internal fluid passage U through which coolant flows may be provided inside the cooling body H2.

The coolant inflow fluid passage 921 may be a passage through which the coolant supplied from the coolant supply unit moves to the cooling body H2. One end of the coolant inflow fluid passage 921 may be connected to the coolant supply unit, and the other end of the coolant inflow fluid passage 921 may be connected to the internal fluid passage U of the cooling body H2.

The coolant discharge fluid passage 922 may be a passage through which the coolant is discharged to the outside of the chilling unit 920. In this case, the coolant discharge fluid passage 922 and the coolant inflow fluid passage 921 may be respectively connected to both ends of the internal fluid passage U. Therefore, the coolant flowing in through the coolant inflow fluid passage 921 may exchange heat with the fume collection unit 910 while passing through the internal fluid passage U, to cool the fume collection unit 910. Thereafter, the coolant may be discharged to an external space of the cooling body H2 through the coolant discharge fluid passage 922.

The chilling unit 920 may be disposed on one side of the fume collection unit 910. In an embodiment, the chilling unit 920 may be disposed below the fume collection unit 910, as illustrated in FIG. 7. In this case, the cooling body H2 may be arranged such that an upper surface thereof is in contact with a lower surface of the housing H1 of the fume collection unit 910. In this case, the coolant inflow fluid passage 921 may be connected to one side of the cooling body H2, and the coolant discharge fluid passage 922 may be connected to the other side of the cooling body H2. In this case, the one side of the cooling body H2 may be a position adjacently to one side, among two opposing sides of the cooling body H2, and the other side of the cooling body H2 may be a position adjacently to the other side, among the two sides of the cooling body H2. For this reason, the coolant inflow fluid passage 921 and the coolant discharge fluid passage 922 may be arranged to face each other.

In this case, the inlet portion 911 of the fume collection unit 910 may be disposed in the housing H1 to be located on an opposite side from the coolant inflow fluid passage 921. As an example, the inlet portion 911 may be connected to an upper end portion of the housing H1. In this case, the inlet portion 911 may be disposed on a side surface of the housing H1 located on an opposite side of the coolant inflow fluid passage 921, to be as far away from the coolant inflow fluid passage 921 as possible. As a result, a decrease in temperature of the connection portion 911a due to a low-temperature coolant newly flowing into the cooling body H2 may be minimized. The outlet portion 912 may be disposed in a lower end portion of the housing H1, such that the mixed gas flowing in through the inlet portion 911 descends in the housing H1 while passing through the fume trap portion F, and is then discharged through the outlet portion 912.

As an operation, prior to the baking process, progressing, warpage may occur in the substrate W on which a liquid film is formed, which bends as it moves away from a center thereof. The warpage may occur in various forms, such as, for example, a central portion of the substrate W being bent in a convex shape in a downward or upward direction, or a combination of the two shapes.

To solve this problem, the vacuum hole 511b may be formed in the hot plate 511 on which the substrate W is supported. The vacuum hole 511b may be formed to penetrate from an upper end to a lower end of the hot plate 511. In this case, the vacuum hole 511b may be provided in plural, and may be distributed over an entire area of the hot plate 511. The vacuum unit 930 may reduce pressure in a space between the substrate W and the hot plate 511 through the vacuum hole 511b while the heat-treatment process is in progress. As a result, the substrate W may be vacuum-adsorbed onto the hot plate 511, to prevent a phenomenon of bending the substrate W during the heat-treatment process. The vacuum unit 930 may be formed with, for example, a vacuum pump or the like.

The vacuum unit 930 may be connected to the fume collection unit 910 through the outlet portion 912. In addition, since the fume collection unit 910 may be connected to the heating unit HU through the inlet portion 911, when the vacuum unit 930 sucks air, it flows from the heating unit HU through the fume collection unit 910. An airflow moving toward the vacuum unit 930 may be formed.

The vacuum unit 930 may be configured to convert between an active state in which the substrate W is vacuum-adsorbed on the hot plate and a non-active state in which the vacuum-adsorption of the substrate W stops. In the active state, a mixed gas containing fumes may be intaken through the vacuum hole 511b, and the substrate W may be vacuum-adsorbed on the hot plate 511 by air intake of the vacuum unit 930. In this case, the mixed gas in the bake chamber 510 may pass through the inlet portion 911 through the vacuum hole 511b, and may move into the internal space of the fume collection unit 910.

In the non-active state, the vacuum unit 930 may stop the air intake operation described above. As a result, a flow rate moving to the fume collection unit 910 through the inlet portion 911 may be reduced. Even when the vacuum unit 930 is in the non-active state, an airflow from the heating unit HU to the fume collection unit 910 may be formed due to a difference in internal air pressure of the apparatus 1. As a result, the mixed gas containing fumes may move to the fume collection unit 910 through the inlet portion 911.

In the conventional case, due to design limitations of the apparatus, when cooling the fume collection unit 910, it is common that a separate coolant supply device is not provided, and the coolant is supplied from a coolant supply unit, which supplies the coolant to the chilling plate of the heating unit HU, to the chilling unit 920. In this case, to prevent the substrate W disposed in the bake chamber 510 from overheating, since the chilling plate of the heating unit HU requires constant cooling, the coolant supply unit should be kept in an ON state. Therefore, the coolant may be always supplied to the chilling unit 920, and cooling of the fume collection unit 910 may continue regardless of whether the vacuum unit 930 is operating.

In this case, as illustrated in FIG. 4, a chilling unit 920 of a conventional apparatus for processing a substrate may not be provided with a bypass fluid passage. Therefore, when a coolant supply unit is in an ON state, supply of a coolant to the chilling unit 920 may not be controlled. For example, regardless of whether a substrate W is supplied and discharged, and whether a vacuum unit 930 sucks air (active state/non-active state), the chilling unit 920 may continue to cool a fume collection unit 910. Therefore, a temperature of the fume collection unit 910 and a temperature of a connection portion 911a may be maintained in a low state. In this case, when the vacuum unit 930 is in a non-active state, a flow rate of gas passing through an inlet portion 911 and the connection portion 911a may be greatly reduced, and fumes contained in a mixed gas passing through the inlet portion 911 may be cooled and solidified in the connection portion 911a, to occur a problem in which the connection portion 911a may be blocked by the fumes. Hereinafter, specific features of a fume processing module 900 of the present disclosure and a method for processing a substrate using the same will be described to prevent the above-described problems.

Referring again to FIGS. 5 to 7, a fume processing module 900 according to an embodiment (hereinafter, Inventive Example 1) of the present disclosure may include a fume collection unit 910, a chilling unit 920, and a vacuum unit 930, as described above, and the chilling unit 920 may further include a bypass fluid passage 923.

The bypass fluid passage 923 may be disposed between a coolant inflow fluid passage 921 and a coolant discharge fluid passage 922. The bypass fluid passage 923 may connect a portion of the coolant inflow fluid passage 921 and a portion of the coolant discharge fluid passage 922, to form a bypass through which coolant may move directly to the coolant discharge fluid passage 922. By the bypass, a coolant may be selectively supplied to the chilling unit 920.

The apparatus 1 may further include a controller (not illustrated). The controller may control a supply state of the coolant to the chilling unit 920. For example, the controller may be implemented as a circuit board mounted on a control computer of an apparatus 1 for processing a substrate, a computer chip mounted on the circuit board, software embedded in the computer chip or in the control computer, or the like.

The controller may control whether or not coolant is supplied to the chilling unit 920. In this case, the controller may selectively open and close the bypass fluid passage 923, based on whether the vacuum unit 930 is active or whether a substrate W is supplied to a heating unit HU.

For example, the controller may close the bypass fluid passage 923 before the substrate W is supplied to the heating unit HU. Additionally, the controller may close the bypass fluid passage 923 when the substrate W is discharged from the heating unit HU. In this case, a time point of closing the bypass fluid passage 923 may be immediately before or immediately after the substrate W is discharged from the heating unit HU. In this case, a coolant supplied from a coolant supply device may move along the coolant inflow fluid passage 921, and may be supplied to the chilling unit 920. When the substrate W is supplied to the heating unit HU, the controller may open the bypass fluid passage 923. In this case, a coolant supplied from the coolant supply device may be moved to and discharged from the coolant discharge fluid passage 922 through the bypass fluid passage 923. As a result, the coolant may not be supplied to the chilling unit 920. Opening and closing of the bypass fluid passage 923 may be performed through an operation of a valve installed in the bypass fluid passage 923.

As another example, when the substrate W is supplied to the heating unit HU, the vacuum unit 930 may be converted to an active state. In this case, a time point at which the vacuum unit 930 is converted to the active state may be, for example, at the same time or immediately after the substrate W is supplied to the heating unit HU. As another example, the vacuum unit 930 may be converted into the active state before the substrate W is transferred into the heating unit HU and after the substrate W is seated on a hot plate 511, or immediately after the substrate W is seated on the hot plate 511.

When the vacuum unit 930 is converted into the active state, the controller may close the bypass fluid passage 923, and may control the coolant to be supplied to the chilling unit 910. In this case, more specifically, the controller may close the bypass fluid passage 923 before a mixed gas containing fumes flows through the inlet portion 911 due to the converting of the active state of the vacuum unit 930.

Additionally, when the substrate W is discharged from the heating unit HU, the vacuum unit 930 may be converted into a non-active state. When the vacuum unit 930 is in the non-active state, the controller may open the bypass fluid passage 923, and may control the coolant not to be supplied to the chilling unit 910. In this case, the coolant may move to the coolant discharge fluid passage 922 through the bypass fluid passage 923, and may be discharged externally. In this case, a time point at which the vacuum unit 930 is converted into the non-active state may be, for example, at the same time as the substrate W is discharged from the heating unit HU, or immediately after the substrate W is discharged. As another example, the vacuum unit 930 may be converted to the non-active state immediately before or immediately after the substrate W is separated from the hot plate 511.

As illustrated in FIG. 5, when the substrate W is supplied to the heating unit HU and the vacuum unit 930 is converted into the active state, the controller may close the bypass fluid passage 923 to move the coolant to the chilling unit 920. In this case, the heating unit HU may include a sensor (not illustrated) detecting the substrate W. For example, the sensor may be disposed in a bake chamber 510, and may detect the substrate W transported into the heating unit HU. As another example, the sensor may be disposed on the hot plate 511, and may detect whether the substrate W is seated on the hot plate 511 by sensing a change in weight.

When the sensor senses that the substrate W has been supplied, the controller may close the bypass fluid passage 923. Therefore, the coolant flowing in from the coolant supply device may be introduced into the chilling unit 920, and the chilling unit 920 may cool the fume collection unit 910 using the coolant.

As illustrated in FIG. 6, before the substrate W is supplied to the heating unit HU and at the time at which the substrate W is discharged from the heating unit HU, when the vacuum unit 930 is converted to a non-active state, the controller may open the bypass fluid passage 923 to change a movement path of the coolant such that the coolant is not supplied to the chilling unit 920. In this case, the controller may use detection results of the above-mentioned sensor to check whether the substrate W is supplied or discharged.

When the controller senses that the substrate W has separated from the hot plate 511 or has moved out of the heating unit HU, the controller may open the bypass fluid passage 923. In this case, the coolant flowing in from the coolant supply device may pass through the bypass fluid passage 923, and may be discharged externally through the coolant discharge fluid passage 922. In this manner, the controller may control to supply the coolant, to stop a cooling operation of the chilling unit 920.

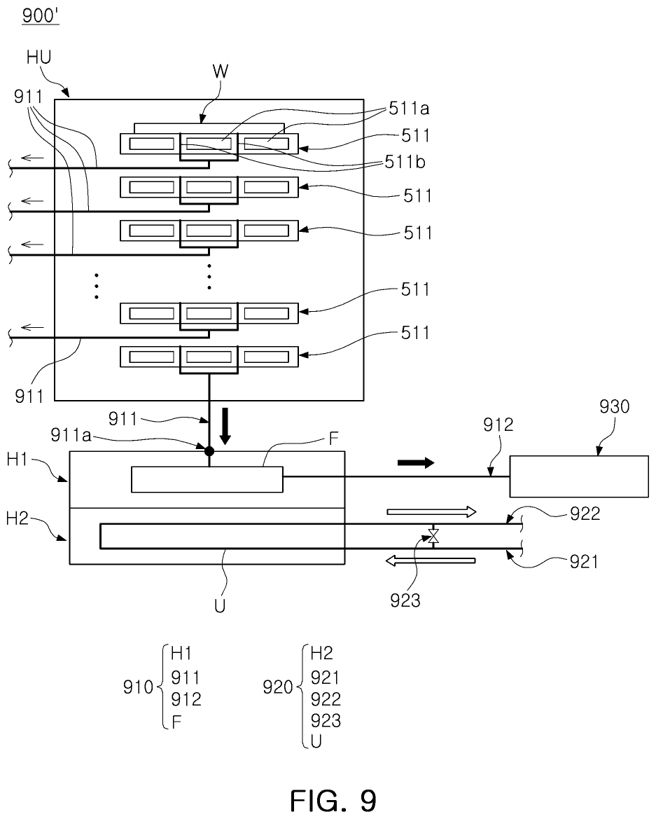

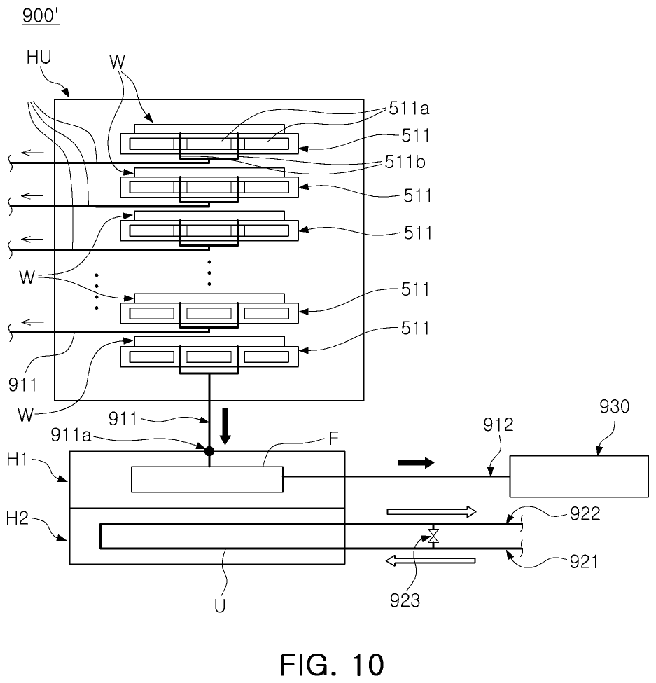

FIG. 8 schematically illustrates a state in which a coolant moves through a bypass fluid passage in a fume processing module according to another embodiment of the present disclosure. FIG. 9 schematically illustrates a state in which a coolant begins to be supplied to a chilling unit in the fume processing module of FIG. 8. FIG. 10 schematically illustrates a state in which a coolant is supplied to a chilling unit in the fume processing module of FIG. 8.

Referring to FIGS. 8 to 10, a fume processing module 900′ according to another embodiment (hereinafter, Inventive Example 2) of the present disclosure may include a fume collection unit 910, a chilling unit 920, and a vacuum unit 930, and in this case, the chilling unit 920 may include a bypass fluid passage 923. In addition, an apparatus 1 for processing a substrate may include a controller controlling a movement path of a coolant, based on whether a substrate W is supplied to and discharged from a heating unit HU. Hereinafter, explanation overlapping Inventive Example 1 described above will be omitted, and differences therebetween will be mainly described.

The heating unit HU may include a plurality of hot plates 511. The plurality of hot plates 511 may be disposed in a bake chamber 510. In this case, the hot plates 511 may be spaced apart in the third direction Z. In this case, a plurality of substrates W may be supplied to the heating unit HU, and the supplied substrates W may be seated on each of the hot plates 511, and may be heated.

When the hot plate 511 is provided in plural, the fume collection unit 910 and the vacuum unit 930 may also be provided in plural. In this case, the vacuum units 930 may be connected to the hot plates 511 one by one, respectively, through the fume collection unit 910. Each of the vacuum units 930 may vacuum-adsorb the substrate W disposed on the hot plate 511 connected thereto. Additionally, from fumes generated during a heat-treatment process by each of the hot plates 511 and a mixed gas containing the fumes, the fume collection unit 910 may collect and remove the fumes. The chilling unit 920 may be also provided in plural, such that each of the fume collection units 910 may be cooled.

In the above case, conversion between the active state and the non-active state of the plurality of vacuum units 930 may be performed individually for each of the vacuum units 930. Additionally, supplying of the coolant to the chilling unit 920, or stopping of the same, and cooling of the fume collection unit 910 thereby may also be performed separately. Due to the individual operation, vacuum-adsorption of the substrate W, collection of the fumes, and cooling of the fume collection unit 910 may be performed simultaneously, and at least a portion of the units 910, 920, and 930 may be performed at different times.

As another embodiment, vacuum holes 511b provided in each of the plurality of hot plates 511 may be connected to one fume collection unit 910 through an inlet portion 911 through a connection passage (not illustrated). Through this, while a heat-treatment process is in progress, the substrates W mounted on each of the hot plates 511 may be vacuum-adsorbed by the vacuum unit 930 through the vacuum holes 511b.

The plurality of substrates W may be supplied to the heating unit HU simultaneously or at different times. As an example, the plurality of substrates W may be sequentially supplied one by one to the heating unit HU. In another example, some of the plurality of substrates W may be first supplied to the heating unit HU, and remaining of the plurality of substrates W may then be supplied to the heating unit HU. In this case, when a first substrate W, among the plurality of substrates W, is supplied to the heating unit HU or is seated on the hot plate 511, a coolant may be supplied to the chilling unit 920, and the vacuum unit 930 may be converted into an active state. When the heat-treatment is completed, the substrates W may be sequentially transported to an external space of the heating unit HU. Immediately before or after the last substrate W of the heat-treated substrates W may be discharged from the heating unit HU, the vacuum unit 930 may be converted back into a non-active state, and the coolant may move to pass through the bypass fluid passage 923, to stop cooling of the chilling unit 920.

Although not illustrated in the drawings, in Inventive Example 1 or 2 described above, a plurality of heating units HU equipped with one or at least two hot plates 511 may be provided. In this case, when the substrate W begins to be supplied as a ‘first heating unit HU’ among the plurality of heating units HU, a coolant may be supplied to the chilling unit 920, and the vacuum unit 930 may be converted into the activate state. Thereafter, as the heat-treatment of the substrates W is completed and all of the substrates W are discharged from the ‘last heating unit HU’ among the plurality of heating units HU, the vacuum unit 930 may be converted into the non-active state, and cooling of the chilling unit 920 may be stopped. In this case, the first heating unit HU may refer to a heating unit HU to which a substrate W is first supplied, among the plurality of heating units HU. And, the last heating unit HU may refer to a heating unit HU in which a substrate W discharged last, among the substrates W, is heat-treated.

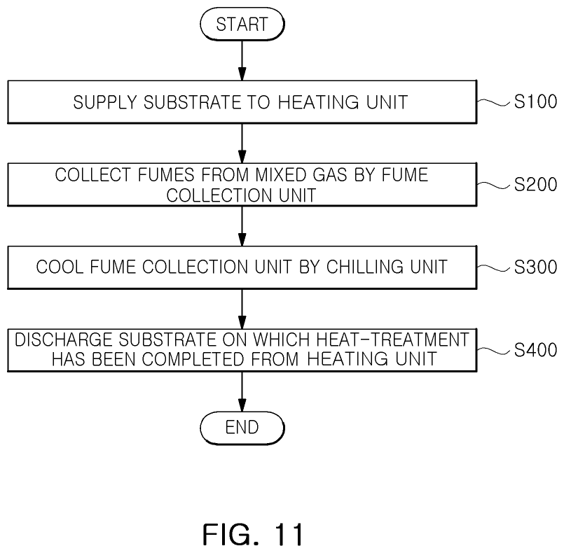

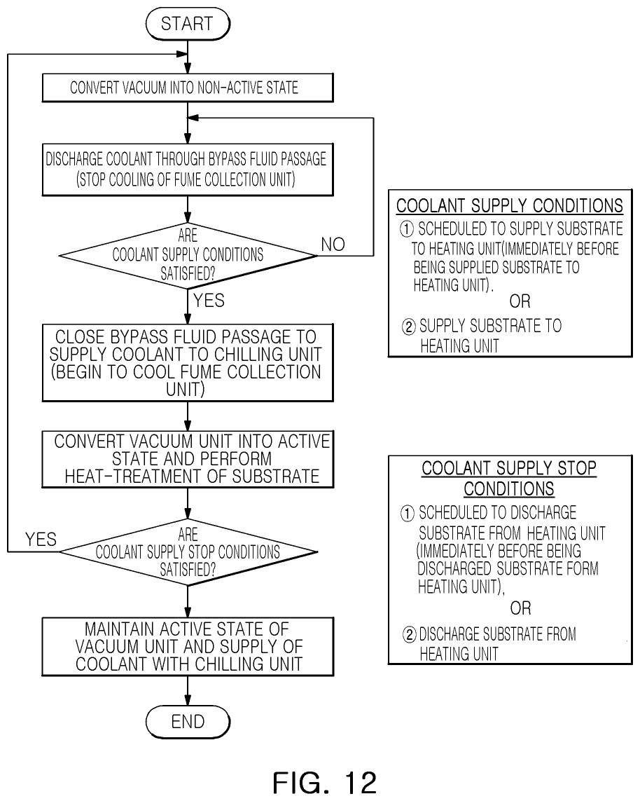

FIG. 11 is a flowchart illustrating a method for processing a substrate using a fume processing module according to the present disclosure. FIG. 12 is a flowchart illustrating some steps of the method of FIG. 11.

Referring to FIGS. 11 and 12, a method for processing a substrate using an apparatus 1 for processing the substrate, including fume processing modules 900 and 900′, according to the above-described embodiments may be as follows. Hereinafter, for convenience of explanation, the description will focus on an embodiment in which a single heating unit HU and a single fume processing module 900 are included.

First, a substrate W may be supplied to a heating unit HU (S100). The substrate W may be transported in a bake chamber 510. The substrate W may be seated on a hot plate 511 by an application robot 421.

Before the substrate W is supplied, a vacuum unit 930 may be in a non-active state. For example, when a plurality of substrates W are transported to the heating unit HU, the vacuum unit 930 may be maintained in a non-active state, until a first substrate W, among the plurality of substrates W, is supplied to the heating unit HU. Additionally, a controller may cause a coolant to move through a bypass fluid passage 923, such that the coolant may not be supplied to a chilling unit 920. As a result, the chilling unit 920 may stop cooling of a fume collection unit 910, until the substrate W is supplied.

Next, the fume collection unit 910 may collect fumes generated when the substrate W is heated (S200). When the substrate W begins to be supplied to the heating unit HU, the vacuum unit 930 may be converted from a non-active state to an active state. The substrate W may be heated in a vacuum-adsorbed state on the hot plate 511 by the vacuum unit 930. In this case, the substrate W may be heated by a heating means 511a, and a mixed gas containing fumes may be generated during this heat-treatment process. This mixed gas may move to the fume collection unit 910 through a vacuum hole 511b and an inlet portion 911. The mixed gas may move into the fume collection unit 910, may be filtered by a fume trap portion F, and may then be discharged through an outlet portion 912.

Next, the chilling unit 920 may cool the fume collection unit 910 (S300). When coolant supply conditions are satisfied, the controller may supply the coolant to the chilling unit 920. In this case, the coolant supply conditions refer to a case in which the substrate W is scheduled to be supplied to the heating unit HU (e.g., immediately before being supplied), as described above, or a case in which the supply to the heating unit HU has been completed (e.g., immediately after being supplied). Additionally, the coolant supply conditions may include a case in which the vacuum unit 930 is converted into the active state (e.g., immediately after converting to the active state, or after converting to the active state and a predetermined time has then elapsed).

In this case, the controller may control to close the bypass fluid passage 923 and supply the coolant to the chilling unit 920 through a coolant inflow fluid passage 921. Thereafter, the coolant may cool the fume collection unit 910 while moving along an internal fluid passage of the chilling unit 920. In this case, the coolant may begin to be supplied to the chilling unit 920, for example, immediately after the vacuum unit 930 is converted to the active state in S200. As another example, the coolant may be supplied to the chilling unit 920 at the same time that the vacuum unit 930 is converted to the active state. The coolant may pass through a cooling fluid passage, and may be discharged through a coolant discharge fluid passage 922.

Next, the substrate W on which heat-treatment has been completed may be discharged from the heating unit HU (S400). In this case, when coolant supply stopping conditions are satisfied, the controller may stop the supply of coolant to the chilling unit 920. In this case, the coolant supply stopping conditions refer to a case in which the substrate W is scheduled to be discharged to the heating unit HU (e.g., immediately before being discharged), or a case in which the substrate W has been discharged to the heating unit HU (e.g., immediately after being discharged), as described above. In this case, the controller may control to open the bypass fluid passage 923 and not supply the coolant to the chilling unit 920, to stop cooling of the fume collection unit 910.

The heat-treated substrate W may be transported to a position for the next process. Additionally, when the discharge of the substrates W from the heating unit HU is completed, the vacuum unit 930 may be converted back to the non-active state. Thereafter, as the next substrate W before heat-treatment is supplied, the operations described above may be repeatedly performed.

A method for processing a substrate according to embodiments of the present disclosure, as described above, may selectively supply a coolant to a chilling unit 920 using a bypass fluid passage 923, based on whether a substrate W is supplied/discharged and whether a vacuum unit 930 is operating. In addition, when the substrate W is supplied to a heating unit HU and vacuum-adsorbed to supply the coolant, but when the vacuum unit 930 is in a non-active state to stop supply of the coolant, such that, in an inlet portion 911 of a fume collection unit 910 and a peripheral portion 911a thereof, fumes may be prevented from cooling and solidifying. As a result, fume collection performance of a fume processing module 900 may be improved.

In the above embodiments, an apparatus for processing a substrate, of the present disclosure, has been described as an embodiment applied to a photo process, but the present disclosure is not limited thereto, and as long as it may be used as an apparatus for removing fumes generated in a process of heating the substrate, it may be obvious to those skilled in the art that it may be applied to various processes such as an etching process, a testing process, a packaging process, or the like, and this will also fall in the scope of the present disclosure.

According to embodiments of the present disclosure, a method for processing a substrate may selectively supply a coolant to a chilling unit using a bypass fluid passage, based on whether a substrate is supplied/discharged and whether a vacuum unit is operating. In addition, when the substrate is supplied to a heating unit and vacuum-adsorbed to supply the coolant, but when the vacuum unit is in a non-active state to stop supply of the coolant, such that, in an inlet portion of a fume collection unit and a peripheral portion thereof, fumes may be prevented from cooling and solidifying. As a result, fume collection performance of a fume processing module may be improved.

While example embodiments have been illustrated and described above, it will be apparent to those skilled in the art that modifications and variations could be made without departing from the scope of the present disclosure as defined by the appended claims.

What is claimed is:

1. An apparatus for processing a substrate, comprising:
a heating unit heating the substrate and including a hot plate having a vacuum hole;
a fume collection unit including a housing, an inlet portion connected to the vacuum hole and introducing a mixed gas containing fumes generated in heating the substrate within an internal space of the housing, and an outlet portion discharging a gas from which the fumes have been removed to an external space of the housing;
a vacuum unit connected to the fume collection unit and vacuum-adsorbing the substrate onto the hot plate when the substrate is heated; and
a chilling unit disposed adjacently to the fume collection unit, and including a cooling body, a coolant inflow fluid passage introducing a coolant into the cooling body, a coolant discharge fluid passage discharging the coolant from the cooling body, and a bypass fluid passage connecting the coolant inflow fluid passage and the coolant discharge fluid passage.

2. The apparatus of claim 1, wherein the coolant inflow fluid passage is connected to one side of the cooling body, and
the coolant discharge fluid passage is connected to the other side of the cooling body.

3. The apparatus of claim 2, wherein the chilling unit is disposed on one side of the fume collection unit, and
the inlet portion is connected to the housing to be opposite to the coolant inflow fluid passage.

4. The apparatus of claim 1, wherein the vacuum unit converts between an active state in which the substrate is vacuum-adsorbed on the hot plate and a non-active state in which the vacuum-adsorption of the substrate stops.

5. The apparatus of claim 4, further comprising a controller controlling the chilling unit to selectively cool the fume collection unit, based on whether the vacuum unit is in the active state or whether the substrate is supplied to the heating unit.

6. The apparatus of claim 5, wherein the controller controls the coolant to move to the coolant discharge fluid passage through the bypass fluid passage, when the vacuum unit is in the non-active state, and controls the coolant to be supplied to the chilling unit, when the vacuum unit converts from the non-active state to the active state.

7. The apparatus of claim 5, wherein the controller controls the coolant to move to the chilling unit through the coolant inflow fluid passage, when the substrate is supplied to the heating unit, and controls the coolant to move to the coolant discharge fluid passage through the bypass fluid passage, immediately before or immediately after the substrate is discharged from the heating unit.

8. The apparatus of claim 7, wherein the controller controls the coolant to be supplied to the chilling unit, before starting a heat-treatment process of the substrate and while the heat-treatment process is performed in the heating unit, and controls stop of the supply of the coolant to the chilling unit, immediately before or immediately after the heat-treatment process is completed.

9. The apparatus of claim 5, further comprising an inlet portion heater disposed on one side of the inlet portion and heating a connection portion in which the inlet portion and the fume collection unit are connected.

10. The apparatus of claim 1, wherein the heating unit is provided in plural, and
the fume collection unit is provided in plural, and the plurality of fume collection units are connected to the plurality of heating units, respectively.

11. A method for processing a substrate, comprising:
supplying the substrate to a hot plate provided in a heating unit;
vacuum-adsorbing the substrate onto the hot plate by a vacuum unit;
collecting fumes from a mixed gas introduced from the heating unit by a fume collection unit; and
selectively cooling the fume collection unit or stopping the cooling by a chilling unit.

12. The method of claim 11, wherein the chilling unit comprises a coolant supply unit, a cooling body spaced apart from the coolant supply unit, a coolant inflow fluid passage introducing a coolant supplied from the coolant supply unit into the cooling body, a coolant discharge fluid passage discharging the coolant from the cooling body, and a bypass fluid passage connecting the coolant inflow fluid passage and the coolant discharge fluid passage, and
the bypass fluid passage is disposed between the cooling body and the coolant supply unit.

13. The method of claim 12, wherein, in the vacuum-adsorbing the substrate by a vacuum unit, the vacuum unit converts between an active state in which the substrate is vacuum-adsorbed on the hot plate and a non-active state in which the vacuum-adsorption of the substrate stops.

14. The method of claim 13, wherein, in the cooling the fume collection unit by a chilling unit, the coolant moves to the coolant discharge fluid passage through the bypass fluid passage, when the vacuum unit is in the non-active state, and is supplied to the chilling unit, when the vacuum unit converts to the active state.

15. The method of claim 12, wherein, in the cooling the fume collection unit by a chilling unit, the coolant moves to the chilling unit through the coolant inflow fluid passage, when the substrate is supplied to the heating unit, and move to the coolant discharge fluid passage through the bypass fluid passage, immediately before or immediately after the substrate is discharged from the heating unit.

16. The method of claim 12, wherein, in the cooling the fume collection unit by a chilling unit, the coolant is supplied to the chilling unit, before starting a heat-treatment process of the substrate and while the heat-treatment process is performed in the heating unit, and moves to the coolant discharge fluid passage through the bypass fluid passage, immediately before or immediately after the heat-treatment process is completed.

17. The method of claim 12, wherein, in the supplying the substrate to a hot plate provided in a heating unit, a plurality of the substrate are sequentially supplied to the heating unit.

18. The method of claim 17, wherein, in the cooling the fume collection unit by a chilling unit, the coolant moves to the chilling unit through the coolant inflow fluid passage, when a first substrate, among the plurality of substrates, is supplied, and moves to the coolant discharge fluid passage through the bypass fluid passage, immediately before or immediately after the last substrate, among the plurality of substrates, is discharged from the heating unit.

19. The method of claim 13, further comprising:
heating a connection portion in which the inlet portion and the fume collection unit are connected by an inlet portion heater, when the vacuum unit converts from the active state to the non-active state, the inlet portion heater heats a connection portion where the inlet portion and the fume collection unit are connected.

20. An apparatus for processing a substrate, comprising:
an application module applying a processing liquid on the substrate;
a heating unit disposed on one side of the application module, receiving and heating the substrate on which the application of the processing liquid has been completed, and including a hot plate having a vacuum hole;
a fume collection unit including a housing, an inlet portion connected to the vacuum hole and introducing a mixed gas containing fumes generated in heating the substrate within an internal space of the housing, and an outlet portion discharging a gas from which the fumes have been removed to an external space of the housing;
a chilling unit disposed on one side of the fume collection unit, and including a coolant supply unit, a cooling body spaced apart from the coolant supply unit, a coolant inflow fluid passage introducing a coolant supplied from the coolant supply unit into the cooling body, a coolant discharge fluid passage discharging the coolant from the cooling body, and a bypass fluid passage disposed between the coolant supply unit and the cooling body and connecting the coolant inflow fluid passage and the coolant discharge fluid passage;
a vacuum unit connected to the fume collection unit, vacuum-adsorbing the substrate onto the hot plate when the substrate is heated, and converting between an active state in which the substrate is vacuum-adsorbed on the hot plate and a non-active state in which the vacuum-adsorption of the substrate stops; and
a controller controlling the chilling unit to selectively cool the fume collection unit, based on whether the vacuum unit is in the active state or whether the substrate is supplied to the heating unit,
wherein the controller controls the coolant to be supplied to the chilling unit, when the substrate is seated on the hot plate and the vacuum unit is converted to the active state, and controls the coolant to move to the coolant discharge fluid passage through the bypass fluid passage, immediately before or immediately after the substrate is discharged from the hot plate.
